(19) United States
(12) Patent Application Publication
(10) Pub. No.: US 2008/0145768 A1
(43) Pub. Date: Jun. 19, 2008

(54) METHOD FOR FORMING A FILM PATTERN HAVING A REDUCED PATTERN SIZE

(75) Inventors: Yosuke SAITO, Tokyo (JP); Isao TANAKA, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 11/950,486

(22) Filed: Dec. 5, 2007

(30) Foreign Application Priority Data
Dec. 15, 2006 (JP) 2006-337844

(51) Int. Cl. G03F 1/00; G03F 7/00

(52) U.S. Cl. 430/5; 430/319

(57) ABSTRACT

A method for forming a resist pattern includes: forming a resist mask on a target film by using photolithography, forming a mixing-generation resist film on the resist mask by coating, baking the mixing-generation resist film to form a mixing layer at the interface between the resist mask and the mixing-generation resist film, developing the mixing-generation resist film, and rinsing the resultant mixing-generation resist film to expose the mixing layer which shrinks pattern size of the resist mask.

This application is based upon and claims the benefit of priority from Japanese patent application No. 2006-337844, the disclosure of which is incorporated herein in its entirety by reference.

### BACKGROUND OF THE INVENTION

(a) Field of the Invention

The present invention relates to a method for forming a resist pattern having a reduced pattern size and, more particularly, to a method for forming a resist pattern by using a shrinking technique. The present invention also relates to a method for manufacturing a semiconductor device using the above method.

(b) Description of the Related Art

Development of higher integration of semiconductor devices highlights a photolithographic technology, which is one of the key technologies for achieving the higher integration. The photolithographic technology is used for forming a fine circuit pattern of each element in a semiconductor device. Conventionally, the finer pattern is achieved in the photolithography by employing a shorter wavelength of the optical source; however, the wavelength of the optical source is almost at the lower limit thereof. Thus, a technique referred to as a shrinking technique attracts a lot of attention and is expected to achieve the finer pattern. The shrinking technique will provide a resist mask having a smaller pattern size which is below the wavelength of the optical source used for the photolithography. Known shrinking techniques in the art include one which uses a high-temperature heat treatment for generating a thermal fluidity of the resist film, and another which forms a mixing-generation resist film separately from the resist mask to be used as an etching mask for the patterning.

FIGS. 4A to 4D consecutively show a semiconductor device in a process for forming a mask pattern by using a shrinking technique employing the mixing-generation resist film. As shown in FIG. 4A, an ordinary resist mask 12 having a specific pattern size is formed on a semiconductor wafer 11 by using photolithography, the ordinary resist mask 12 being configured by a chemically-amplified resist (CAR) material. Subsequently, as shown in FIG. 4B, mixing-generation resist is coated on the resist mask 12 to form a mixing-generation resist film 13. Thereafter, as shown in FIG. 4C, a baking treatment is performed for the mixing-generation resist film at a suitable temperature to thereby form a mixing layer 15 at the interface between the ordinary resist mask 12 and the mixing-generation resist film 13.

Thereafter, a development and rinsing treatment is conducted to the mixing-generation resist film 13 by using pure water, to thereby remove the mixing-generation resist film 13. Thus, after the development and rising treatment, as shown in FIG. 4D, a mixing layer 15 is left on the ordinary resist mask 12, thereby reducing the pattern size, i.e., the diameter of openings in the ordinary resist mask 12, by double the thickness of the mixing layer 15. This technique using the mixing-generation resist film is described in Patent Publication JP-1993-166717A, for example.

In the technique using the mixing-generation resist film as described above, there is a problem in that a low solubility material 16, as shown in FIG. 4C, is generated within the mixing-generation resist film 13 during the baking treatment thereof. The thus generated low solubility material 16 may be attached onto the exposed surface of the mixing layer 15 after the development and rinsing treatment using the pure water, as shown in FIG. 4D. The low solubility material 16 attached onto the mixing layer 15 forms stains or spot-like defects on the mixing layer 15. The spot-like defects may be removed by a long-time rinsing treatment or by using a special rinse agent such as including a surfactant. However, removal of such spot-like defects is accompanied by a lower throughput, cost increase due to the special rinse agent, alteration of the development and rinsing unit due to the employment of the special rinse agent etc., thereby raising the overall cost of the photolithography. Thus, it is desired to remove the low solubility material in the mixing-generation resist or spot-like defects attached onto the mixing layer substantially without an increase of the cost.

### SUMMARY OF THE INVENTION

In view of the above, it is an object of the present invention to provide an improved method for forming a fine resist pattern by using a shrinking technique, which is capable of suppressing occurring of spot-like defects substantially without an increase of the cost.

It is another object of the present invention to provide a method for manufacturing a semiconductor device by using such a method for forming the fine resist pattern.

The present invention provides a method for forming a resist pattern including: forming a resist mask having a specific pattern on a target film; forming a mixing-generation resist film on the resist mask; baking the mixing-generation resist film to form a mixing layer at an interface between the resist mask and the mixing-generation resist film; and developing the mixing-generation resist film by using a developing solution including 0.05 to 0.37 wt % tetramethylammonium hydroxide.

The present invention also provides a method for manufacturing a semiconductor device including: forming a target film overlying a substrate; forming a resist mask having a specific pattern on the target film; forming a mixing-generation resist film on the resist mask; baking the mixing-generation resist film to form a mixing layer at an interface between the resist mask and the mixing-generation resist film; and developing the mixing-generation resist film by using a developing solution including 0.05 to 0.37 wt % tetramethylammonium hydroxide.

The above and other objects, features and advantages of the present invention will be more apparent from the following description, referring to the accompanying drawings.

### BRIEF DESCRIPTION OF THE DRAWINGS

FIGS. 1A to 1F are sectional view of a semiconductor device, showing consecutive steps of a process for forming a resist pattern according to an embodiment of the present invention.

FIG. 2 is top plan view of a wafer showing the spot-like defects on the surface of the mixing layer formed by the method of the embodiment and a comparative process.

FIG. 3 is a graph showing the relationship between the number of spot-like defects on the mixing layer and the concentration of TMAH and between the solubility of the mixing layer and the concentration of tetramethylammonium hydroxide (TMAH).

FIGS. 4A to 4D are sectional view of a semiconductor device, showing consecutive steps of a process for forming a resist pattern by using the related shrinking technique.

### PREFERRED EMBODIMENT OF THE INVENTION

Before describing an embodiment of the present invention, the principle of the present invention will be described for a better understanding of the present invention. In an example of the present invention, development of the mixing-generation resist film is performed using a diluted alkaline developing solution containing therein as low as 0.05 to 0.37 weight percent (wt %) TMAH. By using this developing solution, the low solubility material, which is generated within the mixing-generation resist film and causes the spot-like defects on the mixing layer, is dissolved in the developing solution.

Although a developing solution including TMAH is used for developing a photoresist film in a conventional technique, the concentration of TMAH used as the developing solution of the photoresist film is as high as 2.38 wt %, for example. The developing solution including 2.38 wt % TMAH will dissolve the mixing layer formed by the baking treatment as well as the low solubility material desired to be removed, thereby impeding achievement of the finer pattern size and reducing the advantage of the pattern shrinking process. Thus, the present invention uses such a diluted developing solution, thereby leaving the mixing layer substantially as it is and yet removing the low solubility material.

Now, an exemplary embodiment of the present invention will be described with reference to accompanying drawings, wherein similar constituent elements are designated by similar reference numerals throughout the drawings.

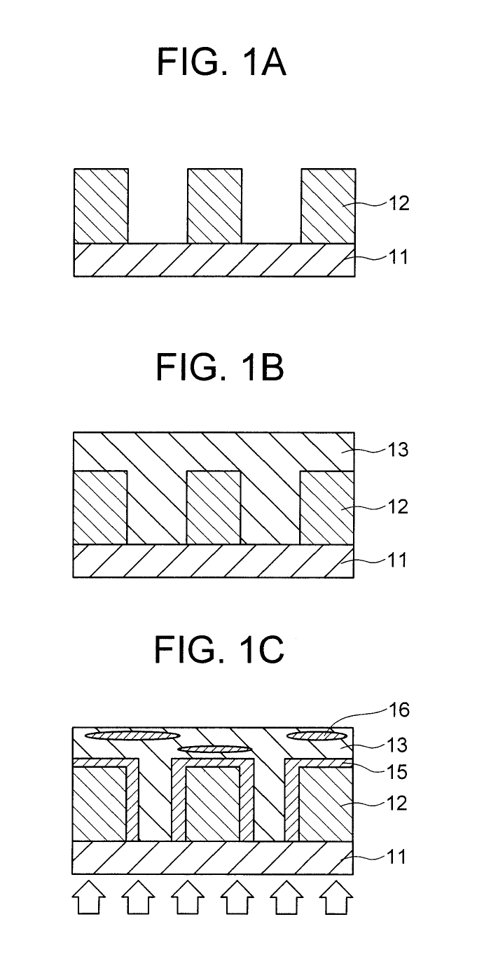

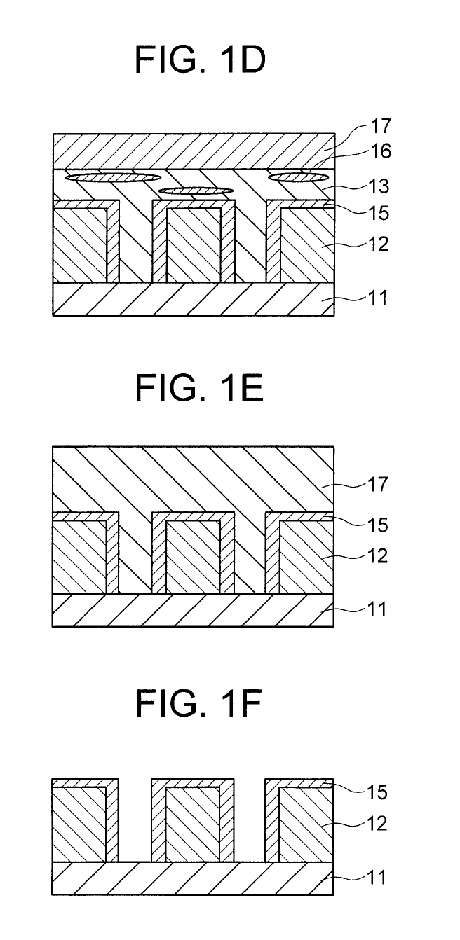

FIGS. 1A to 1F are sectional views of a semiconductor device (wafer), showing consecutive steps of a process for forming a resist mask in the semiconductor device. As shown in FIG. 1A, a resist mask 12 is formed on a semiconductor substrate 11 including a target film on the surface thereof, which is to be patterned later, by using an ordinary photolithographic process. The resist mask 12 is formed from a resist material such as methacrylic ArF resist supplied from Tokyo Oka Inc. The target film may be an insulation film in which through-holes or contact holes are to be formed in a semiconductor device manufacturing process.

Subsequently, as shown in FIG. 1B, mixing-generation resist is coated on the resist mask 12 to form a mixing-generation resist film 13. R602 (trademark: supplied from AZ_EM Inc.), for example, is used as the mixing-generation resist. The thickness of the mixing-generation resist film 13 is 220 nm, for example. Subsequently, the substrate temperature is raised up to 175 degrees C., followed by maintaining the resultant substrate temperature for 90 seconds to thereby conduct a baking treatment of the mixing-generation resist film 13. After the baking treatment, a mixing layer 15 is formed at the interface between the resist mask 12 and the mixing-generation resist films 13, i.e., on the surface of the resist mask 12. After the baking treatment, a low solubility material 16, which causes spot-like defects later, is formed within the mixing-generation resist film 13, as depicted in FIG. 1C. The baking treatment may be referred to as mixing-baking treatment in the shrinking technique.

Thereafter, the resultant substrate is subjected to a developing treatment using a developing unit. A developing nozzle installed in the developing unit and having a diluting function is used to coat the surface of the thus baked mixing-generation resist film 13 with diluted alkaline developing solution 17, as shown in FIG 1D. The diluted alkaline developing solution 17 includes 0.05 to 0.37 wt % TMAH. The developing unit may be LITHIUS (trademark) supplied from Tokyo Electron, Ltd., and the developing nozzle may be NewLD_Nozzle (trademark) included in LITHIUS as the standard equipment. The wafer is then maintained for 45 seconds in this state wherein the entire surface is covered with the 0.05 to 0.37 wt % TMAH 17, i.e., the developing solution, thereby dissolving the baked mixing-generation resist film 13, as shown in FIG. 1E. Thereafter, a rinsing treatment is conducted using pure water to obtain a fine pattern including a mixing layer 15 which shrinks the pattern size of the photoresist mask 12 at the openings, as shown in FIG. 1F. As depicted in FIG. 1F, the developing treatment using the diluted developing solution, which removes the low solubility material 16 from the mixing-generation resist film 13, provides a resist pattern without the point-like defects after the rinsing.

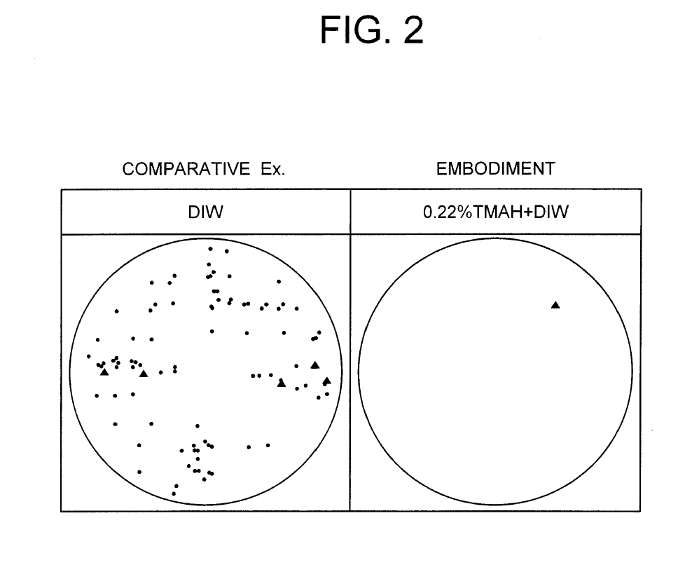

FIG. 2 shows a map on a semiconductor wafer, representing the presence of spot-like defects after the rinsing treatment using the method of the above embodiment and a comparative process. The comparative process used pure water, referred to as de-ionized water (DIW), in the developing and rinsing treatment, whereas the present embodiment used 0.22 wt % TMAH in the developing treatment and DIW in the rinsing treatment. As depicted in FIG. 2, the comparative process caused occurring of 488 point-like defects per wafer, whereas the present embodiment using 0.22 wt % TMAH caused occurring of two point-like defects per wafer. It is thus confirmed that the process of the above embodiment significantly reduces the number of point-like defects formed on the mixing layer in the baking treatment.

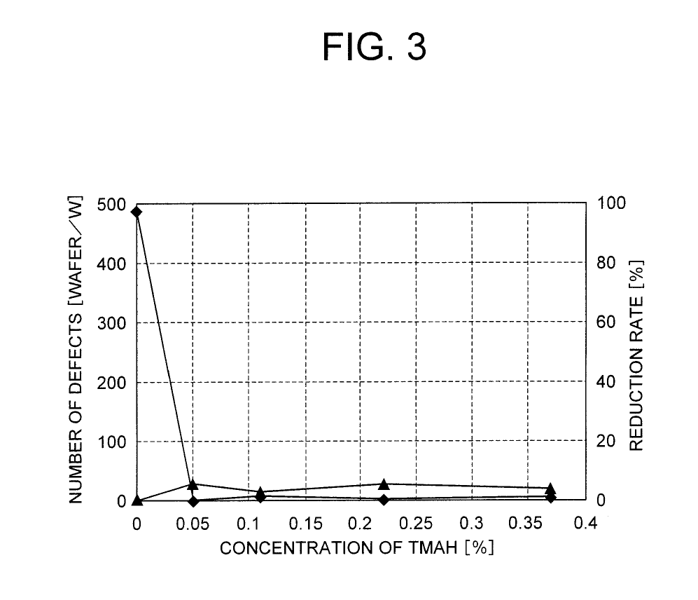

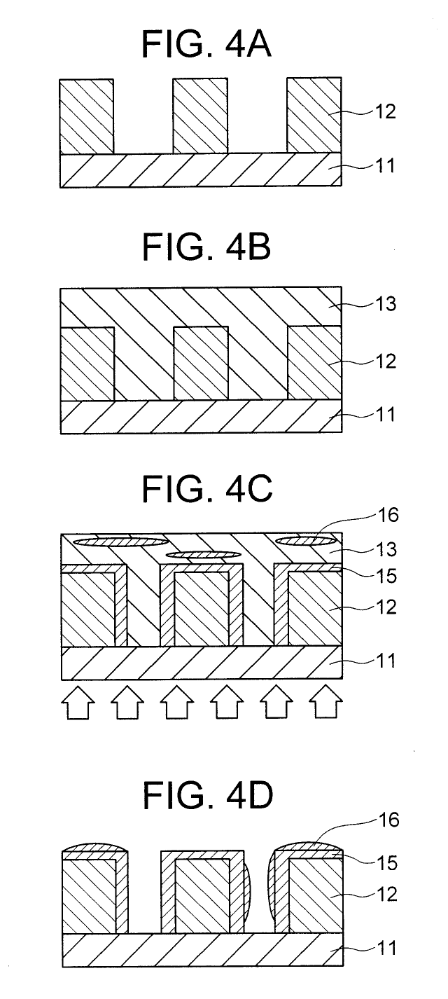

FIG. 3 shows the results of an experiment conducted for investigating the relationship between the concentration of TMAH used in the developing solution and the number of point-like defects occurring after the developing treatment using the TMAH and a subsequent rinsing treatment, and between the concentration of TMAH and the amount of dissolved mixing layer after the developing treatment and the rising treatment. In FIG. 3, circular dots represent the number of point-like defects occurring after the rinsing treatment, whereas triangular dots represent the reduction rate (%) of the mixing layer caused by dissolution thereof in the developing solution. The concentration of TMAH in the developing solution was varied during the experiment from zero to 0.37 wt %. As shown in FIG. 3, a developing treatment using zero weight percent TMAH, i.e., pure water, provided 488 point-like defects, whereas a developing treatment using 0.05 to 0.37 wt % TMAH achieved a significant reduction of the point-like defects, without a substantially increase in the amount of mixing layer dissolved in the developing solution.

In FIG. 3, the amount of dissolved mixing layer is 4% or less of the total mixing layer in the case of developing treatment using the above range of concentration for the TMAH. The dissolved amount of 4% is well within the allowable range in the ordinary process for forming the resist pattern. In addition, the dissolved amount scarcely varies within the range of 0.05 to 0.37 wt % of TMAH. This means the present embodiment is effective to improve the quality of the mixing layer with a limited reduction in the shrinking effect caused by the low solubility material.

As described above, the present embodiment employs a development treatment for the mixing-generation resist film after the baking treatment, by using a diluted alkaline developing solution including 0.05 to 0.37 wt % TMAH, followed by a rinsing treatment using pure water. The developing treatment performed between the baking treatment and the rinsing treatment dissolves the low solubility material generated in the mixing-generation layer during the baking treatment, thereby preventing occurrence of the point-like defects on the resultant mixing layer. That is, the above embodiment reduces the number of point-like defects at a lower cost, by preventing a long-time rinsing treatment, removing the necessity of using a special rinse agent, and suppressing reduction in the throughput of the photolithography.

While the invention has been particularly shown and described with reference to exemplary embodiment and modifications thereof, the invention is not limited to these embodiment and modifications. It will be understood by those of ordinary skill in the art that various changes in form and details may be made therein without departing from the spirit and scope of the present invention as defined in the claims.

What is claimed is:

1. A method for forming a resist pattern comprising:
forming a resist mask having a specific pattern on a target film;
forming a mixing-generation resist film on said resist mask;
baking said mixing-generation resist film to form a mixing layer at an interface between said resist mask and said mixing-generation resist film; and
developing said mixing-generation resist film by using a developing solution including 0.05 to 0.37 wt % tetramethylammonium hydroxide.

2. The method according to claim 1, further comprising a rinsing treatment subsequent to said developing.

3. The method according to claim 1, wherein said baking generates a mixing layer at an interface between said resist mask and said mixing-generation resist film.

4. The method according to claim 1, wherein said resist mask includes a chemical amplified resist material.

5. A method for manufacturing a semiconductor device comprising:
forming a target film overlying a substrate;
forming a resist mask having a specific pattern on said target film;
forming a mixing-generation resist film on said resist mask;
baking said mixing-generation resist film to form a mixing layer at an interface between said resist mask and said mixing-generation resist film; and
developing said mixing-generation resist film by using a developing solution including 0.05 to 0.37 wt % tetramethylammonium hydroxide.

6. The method according to claim 5, further comprising a rinsing treatment subsequent to said developing.

7. The method according to claim 5, wherein said baking generates a mixing layer at an interface between said resist mask and said mixing-generation resist film.

8. The method according to claim 7, further comprising etching said target film by using said resist mask and said mixing layer as an etching mask.

9. The method according to claim 5, wherein said resist mask includes a chemical amplified resist material.
